(19) United States
(12) Patent Application Publication
(10) Pub. No.: US 2025/0053097 A1
(43) Pub. Date: Feb. 13, 2025

(54) MACHINE LEARNING MODEL FOR ASYMMETRY-INDUCED OVERLAY ERROR CORRECTION

(71) Applicant: ASML NETHERLANDS B.V., Veldhoven (NL)

(72) Inventors: Kui-Jun HUANG, Shenzhen (CN); Liping REN, San Jose, CA (US)

(21) Appl. No.: 18/716,806

(22) PCT Filed: Nov. 22, 2022
(86) PCT No.: PCT/EP2022/082757

§ 371 Date: Jun. 5, 2024

(30) Foreign Application Priority Data
Dec. 17, 2021 (WO) PCT/CN2021/139212

(51) Int. Cl. G03F 7/00

(52) U.S. Cl. CPC G03F 7/706841; G03F 7/70633

(57) ABSTRACT

A correction to an error of overlay measurement which accounts for target structure asymmetry using a neural network is described. According to embodiments, an overlay measurement accuracy can be improved by accounting for multiple and/or asymmetric perturbations in the target structure. A trained neural network is described which generates a correction value for overlay measurement based on a measure of asymmetry. Based on an as-measured overlay measurement, which may not account for target structure asymmetry, and the correction value, a true overlay measurement is determined-which can exhibit improved accuracy and reduced uncertainty versus uncorrected values.

### CROSS-REFERENCE TO RELATED APPLICATIONS

This application claims priority of International application PCT/CN2021/139212 which was filed on Dec. 17, 2021 and which is incorporated herein in its entirety by reference.

### TECHNICAL FIELD

The present disclosure relates generally to overlay metrology in semiconductor manufacturing, and more specifically to overlay metrology using machine learning.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electromechanical systems (MEMS) and other devices.

As semiconductor manufacturing processes continue to advance, the dimensions of functional elements have continually been reduced. At the same time, the number of functional elements, such as transistors, per device has been steadily increasing, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, source mask optimization (SMO), or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

A correction to an error of an overlay measurement which accounts for target structure asymmetry using a neural network is described. According to embodiments of the present disclosure, an overlay measurement accuracy can be improved by accounting for multiple and/or asymmetric perturbations in the target structure. A trained neural network is described which generates a correction value for overlay measurement based on input of measure distance-to-origin for asymmetry measurement at multiple wavelengths as used in an optical metrology apparatus. Based on the as-measured overlay measurements, which may not account for target structure asymmetry, and the correction value, a total true overlay measurement is determined-which can exhibit improved accuracy and reduced uncertainty versus uncorrected values.

Training data used to train the neural network may comprise data for a set of target structures, including their corresponding distance-to-origin values over multiple wavelengths are labeled with overlay measurement values. In some embodiments, a set of target structures is generated by varying each of a set of perturbation parameters of the target structure to create asymmetric target structures. Overlay measurements and amplitude asymmetry measurements at multiple wavelengths are then simulated based on a model for each of the set of target structures.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 depicts a schematic overview of a lithographic apparatus, according to an embodiment.

FIG. 2 depicts a schematic overview of a lithographic cell, according to an embodiment.

FIG. 3 depicts a schematic representation of holistic lithography, representing a cooperation between three technologies to optimize semiconductor manufacturing, according to an embodiment.

FIG. 4 illustrates an example metrology apparatus, such as a scatterometer, according to an embodiment.

FIGS. 5A and 5B illustrate operation of an example metrology apparatus, such as a diffraction-based metrology apparatus for overlay measurement, according to an embodiment.

FIGS. 6A and 6B illustrate asymmetric amplitude graphs for example target structures used for determining a measure of overlay, according to an embodiment.

FIG. 7 illustrates a summary of operations of a present method for generating a corrected measure of overlay for a target structure accounting for target structure asymmetry, according to an embodiment.

FIG. 8 illustrates a diagram for determining a corrected measure of overlay for target structure accounting target asymmetry using a neural network, according to an embodiment.

FIG. 9A illustrates measures of asymmetry determined for an example target structure, according to an embodiment.

FIG. 9B illustrates example corrections to a measure of overlay determined for an example target structure, according to an embodiment.

FIGS. 10A and 10B illustrate determinations of various measures of asymmetry, according to an embodiment.

FIG. 11 illustrates a exemplary method for generating training data for a neural network, according to an embodiment.

FIGS. 12A-12C illustrate example perturbations of a target structure generated for training a neural network, according to an embodiment.

FIG. 13 is a block diagram of an example computer system, according to an embodiment of the present disclosure.

FIG. 14 is a schematic diagram of another lithographic projection apparatus, according to an embodiment of the present disclosure.

FIG. 15 is a detailed view of a lithographic projection apparatus, according to an embodiment of the present disclosure.

FIG. 16 is a detailed view of a source collector module of the lithographic projection apparatus, according to an embodiment of the present disclosure

### DETAILED DESCRIPTION

In semiconductor manufacturing, the overlay or relative position (e.g., alignment) of various levels of the stack or structure can be determined based on optical measurements from reflections of radiation off one or more layers of the stack or structure. Specially designed target structures can be organized between or among patterns corresponding to devices, where such target structures deflect light in predetermined ways, and where various manufacturing and material parameters can be determined or inferred from such reflections. By monitoring the reflected signals, manufacturing processes can be monitored, calibrated, adjusted and controlled. However, elements other than the alignment or measure of overlay of various layers can affect the optical reflections. For example, asymmetry of the target structure, including asymmetry in a buried layer of the target structure which is not the layer being measured for alignment (such as floor tilt), can also optical reflections.

According to embodiments of the present disclosure, a set of perturbations of the target structure are generated or otherwise acquired. A set of perturbation parameters can be selected for a target structure, where the perturbations of the target structure are generated based on altering the target structure geometry according to the set of perturbation parameters. Such perturbation parameters can include side wall angle (SWA), floor tilt, spacing, stress relief effects, etch loading effects, etc. For each of the perturbations of the target structure, a measure of overlay is determined and at least one measure of asymmetry is simulated. A set of training data is generated based on the measures of asymmetry labeled with the corresponding measures of overlay and a neural network is trained to output a correction to the measure of overlay based on an input measure of asymmetry. For target structures, a corrected measure of overlay which accounts for target asymmetry is determined based on the measure of overlay measured optically and the correction to the measure of overlay output by the trained neural network. The corrected measure of overlay (or referred to as “overlay error correction” herein), which accounts for target asymmetry, can be both more accurate and more certain than measures of overlay which do not account for target asymmetry and can account for target asymmetry due to two or more perturbation parameters where the relationship between a measure of asymmetry and a measure of overlay is nonlinear.

Embodiments of the present disclosure are described in detail with reference to the drawings, which are provided as illustrative examples of the disclosure so as to enable those skilled in the art to practice the disclosure. Notably, the figures and examples below are not meant to limit the scope of the present disclosure to a single embodiment, but other embodiments are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure. Embodiments described as being implemented in software should not be limited thereto, but can include embodiments implemented in hardware, or combinations of software and hardware, and vice-versa, as will be apparent to those skilled in the art, unless otherwise specified herein. In the present specification, an embodiment showing a singular component should not be considered limiting; rather, the disclosure is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

A (e.g., semiconductor) patterning device can comprise, or can form, one or more patterns. The pattern can be generated utilizing CAD (computer-aided design) programs, based on a pattern or design layout, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. The design rules may include and/or specify specific parameters, limits on and/or ranges for parameters, and/or other information. One or more of the design rule limitations and/or parameters may be referred to as a “critical dimension” (CD). A critical dimension of a device can be defined as the smallest width of a line or hole or the smallest space between two lines or two holes, or other features. Thus, the CD determines the overall size and density of the designed device. One of the goals in device fabrication is to faithfully reproduce the original design intent on the substrate (via the patterning device).

The term “mask” or “patterning device” as employed in this text may be broadly interpreted as referring to a generic semiconductor patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

As used herein, the term “patterning process” generally means a process that creates an etched substrate by the application of specified patterns of light as part of a lithography process. However, “patterning process” can also include (e.g., plasma) etching, as many of the features described herein can provide benefits to forming printed patterns using etch (e.g., plasma) processing.

As used herein, the term “pattern” means an idealized pattern that is to be etched on a substrate (e.g., wafer)—e.g., based on the design layout described above. A pattern may comprise, for example, various shape(s), arrangement(s) of features, contour(s), etc.

As used herein, a “printed pattern” means the physical pattern on a substrate that was etched based on a target pattern. The printed pattern can include, for example, troughs, channels, depressions, edges, or other two- and three-dimensional features resulting from a lithography process.

As used herein, the term “prediction model”, “process model”, “electronic model”, and/or “simulation model” (which may be used interchangeably) means a model that includes one or more models that simulate a patterning process. For example, a model can include an optical model (e.g., that models a lens system/projection system used to deliver light in a lithography process and may include modelling the final optical image of light that goes onto a photoresist), a resist model (e.g., that models physical effects of the resist, such as chemical effects due to the light), an OPC model (e.g., that can be used to make target patterns and may include sub-resolution resist features (SRAFs), etc.), an etch (or etch bias) model (e.g., that simulates the physical effects of an etching process on a printed wafer pattern), a source mask optimization (SMO) model, and/or other models.

As used herein, the term “calibrating” means to modify (e.g., improve or tune) and/or validate a model, an algorithm, and/or other components of a present system and/or method.

A patterning system may be a system comprising any or all of the components described above, plus other components configured to performing any or all of the operations associated with these components. A patterning system may include a lithographic projection apparatus, a scanner, system is configured to apply and/or remove resist, etching systems, and/or other systems, for example.

As used herein, the term “diffraction” refers to the behavior of a beam of light or other electromagnetic radiation when encountering an aperture or series of apertures, including a periodic structure or grating. “Diffraction” can include both constructive and destructive interference, including scattering effects and interferometry. As used herein, a “grating” is a periodic structure, which can be one-dimensional (i.e., comprised of posts of dots), two-dimensional, or three-dimensional, and which causes optical interference, scattering, or diffraction. A “grating” can be a diffraction grating.

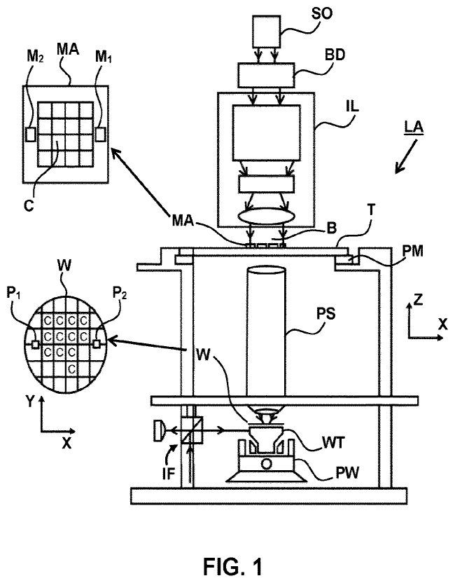

As a brief introduction, FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) T constructed to support a patterning device (e.g., a mask) MA and connected to a first positioner PM configured to accurately position the patterning device MA in accordance with certain parameters, a substrate support (e.g., a wafer table) WT configured to hold a substrate (e.g., a resist coated wafer) W and coupled to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g., via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g., mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

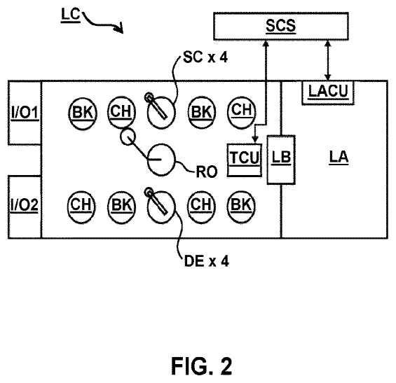

FIG. 2 depicts a schematic overview of a lithographic cell LC. As shown in FIG. 2 the lithographic apparatus LA may form part of lithographic cell LC, also sometimes referred to as a lithocell or (litho) cluster, which often also includes apparatus to perform pre- and post-exposure processes on a substrate W. Conventionally, these include spin coaters SC configured to deposit resist layers, developers DE to develop exposed resist, chill plates CH and bake plates BK, e.g. for conditioning the temperature of substrates, W e.g., for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g., via lithography control unit LACU.

In order for the substrates W (FIG. 1) exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W (FIG. 1), and, in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

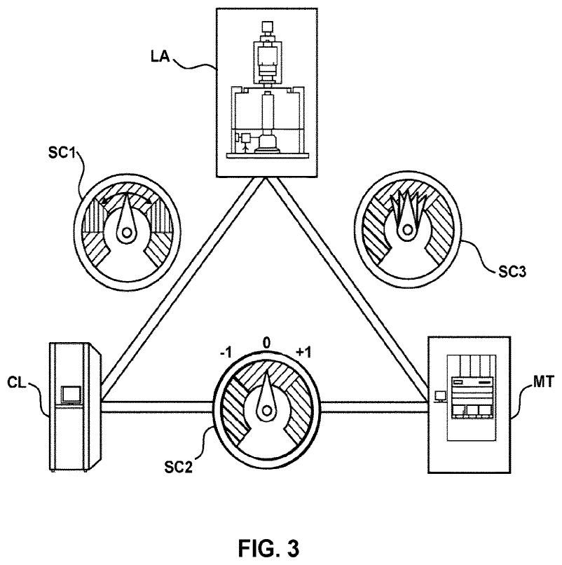

FIG. 3 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g., using input from the metrology tool MT) to predict whether defects may be present due to, for example, sub-optimal processing (depicted in FIG. 3 by the arrow pointing “0” in the second scale SC2).

The metrology apparatus (tool) MT may provide input to the computer system CL to enable accurate simulations and predictions, and may provide feedback to the lithographic apparatus LA to identify possible drifts, e.g., in a calibration status of the lithographic apparatus LA (depicted in FIG. 3 by the multiple arrows in the third scale SC3).

In lithographic processes, it is desirable to make frequent measurements of the structures created, e.g., for process control and verification. Different types of metrology tools MT for making such measurements are known, including scanning electron microscopes or various forms of optical metrology tool, image based or scatterometery-based metrology tools. Scatterometers are versatile instruments which allow measurements of the parameters of a lithographic process by having a sensor in the pupil or a conjugate plane with the pupil of the objective of the scatterometer, measurements usually referred as pupil-based measurements, or by having the sensor in the image plane or a plane conjugate with the image plane, in which case the measurements are usually referred as image or field-based measurements. Such scatterometers and the associated measurement techniques are further described in patent applications US20100328655, US2011102753A1, US20120044470A, US20110249244, US20110026032 or EP1,628,164A, incorporated herein by reference in their entirety. Aforementioned scatterometers may measure features of a substrate such as gratings using light from soft x-ray and visible to near-IR wavelength range, for example.

In some embodiments, a scatterometer MT is an angular resolved scatterometer. In these embodiments, scatterometer reconstruction methods may be applied to the measured signal to reconstruct or calculate properties of a grating and/or other features in a substrate. Such reconstruction may, for example, result from simulating interaction of scattered radiation with a mathematical model of the target structure and comparing the simulation results with those of a measurement. Parameters of the mathematical model are adjusted until the simulated interaction produces a diffraction pattern similar to that observed from the real target.

In some embodiments, scatterometer MT is a spectroscopic scatterometer MT. In these embodiments, spectroscopic scatterometer MT may be configured such that the radiation emitted by a radiation source is directed onto target features of a substrate and the reflected or scattered radiation from the target is directed to a spectrometer detector, which measures a spectrum (i.e., a measurement of intensity as a function of wavelength) of the specular reflected radiation. From this data, the structure or profile of the target giving rise to the detected spectrum may be reconstructed, e.g., by Rigorous Coupled Wave Analysis and non-linear regression or by comparison with a library of simulated spectra.

In some embodiments, scatterometer MT is an ellipsometric scatterometer. The ellipsometric scatterometer allows for determining parameters of a lithographic process by measuring scattered radiation for each polarization states. Such a metrology apparatus (MT) emits polarized light (such as linear, circular, or elliptic) by using, for example, appropriate polarization filters in the illumination section of the metrology apparatus. A source suitable for the metrology apparatus may provide polarized radiation as well. Various embodiments of existing ellipsometric scatterometers are described in U.S. patent application Ser. Nos. 11/451,599, 11/708,678, 12/256,780, 12/486,449, 12/920,968, 12/922,587, 13/000,229, 13/033,135, 13/533,110 and 13/891,410 incorporated herein by reference in their entirety.

In some embodiments, scatterometer MT is adapted to measure the overlay of two misaligned gratings or periodic structures (and/or other target features of a substrate) by measuring asymmetry in the reflected spectrum and/or the detection configuration, the asymmetry being related to the extent of the overlay. The two (typically overlapping) grating structures may be applied in two different layers (not necessarily consecutive layers), and may be formed substantially at the same position on the wafer. The scatterometer may have a symmetrical detection configuration as described e.g., in patent application EP1,628,164A, such that any asymmetry is clearly distinguishable. This provides a way to measure misalignment in gratings. Further examples for measuring overlay may be found in PCT patent application publication no. WO 2011/012624 or US patent application US20160161863, incorporated herein by reference in their entirety.

Focus and dose used in lithography process may be determined by scatterometry (or alternatively by scanning electron microscopy) as described in US patent application US2011-0249244, incorporated herein by reference in its entirety. A single structure (e.g., feature in a substrate) may be used which has a unique combination of critical dimension and sidewall angle measurements for each point in a focus energy matrix (FEM—also referred to as Focus Exposure Matrix). If these unique combinations of critical dimension and sidewall angle are available, the focus and dose values may be uniquely determined from these measurements.

A metrology target may be an ensemble of composite gratings and/or other features in a substrate, formed by a lithographic process, commonly in resist, but also after etch processes, for example. Typically, the pitch and line-width of the structures in the gratings depend on the measurement optics (in particular the NA of the optics) to be able to capture diffraction orders coming from the metrology targets. A diffracted signal may be used to determine shifts between two layers (also referred to “overlay”) or may be used to reconstruct at least part of the original grating as produced by the lithographic process. This reconstruction may be used to provide guidance of the quality of the lithographic process and may be used to control at least part of the lithographic process. Targets may have smaller sub-segmentation which are configured to mimic dimensions of the functional part of the design layout in a target. Due to this sub-segmentation, the targets will behave more similarly to the functional part of the design layout such that the overall process parameter measurements resemble the functional part of the design layout. The targets may be measured in an underfilled mode or in an overfilled mode. In the underfilled mode, the measurement beam generates a spot that is smaller than the overall target. In the overfilled mode, the measurement beam generates a spot that is larger than the overall target. In such overfilled mode, it may also be possible to measure different targets simultaneously, thus determining different processing parameters at the same time.

Overall measurement quality of a lithographic parameter using a specific target is at least partially determined by the measurement recipe used to measure this lithographic parameter. The term “substrate measurement recipe” may include one or more parameters of the measurement itself, one or more parameters of the one or more patterns measured, or both. For example, if the measurement used in a substrate measurement recipe is a diffraction-based optical measurement, one or more of the parameters of the measurement may include the wavelength of the radiation, the polarization of the radiation, the incident angle of radiation relative to the substrate, the orientation of radiation relative to a pattern on the substrate, etc. One of the criteria to select a measurement recipe may, for example, be a sensitivity of one of the measurement parameters to processing variations. More examples are described in US patent application US2016-0161863 and published US patent application US 2016/0370717A1 incorporated herein by reference in its entirety.

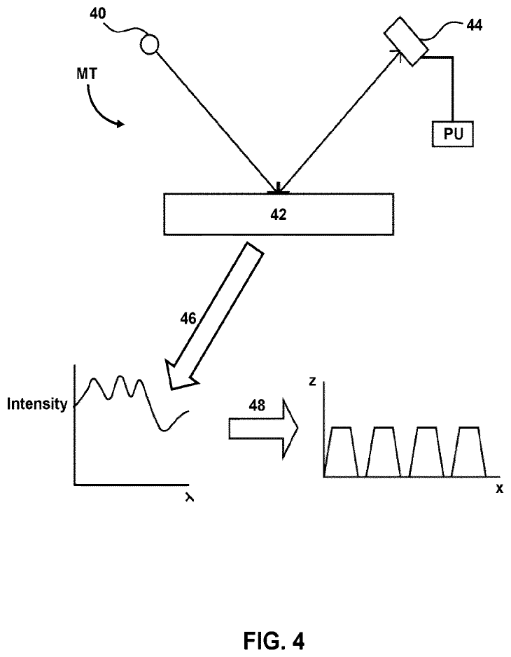

FIG. 4 illustrates an example metrology apparatus (tool) MT, such as a scatterometer. MT comprises a broadband (white light) radiation projector 40 which projects radiation onto a substrate 42. The reflected or scattered radiation is passed to a spectrometer detector 44, which measures a spectrum 46 (i.e., a measurement of intensity as a function of wavelength) of the specular reflected radiation. From this data, the structure or profile giving rise to the detected spectrum may be reconstructed 48 by processing unit PU, e.g., by Rigorous Coupled Wave Analysis and non-linear regression or by comparison with a library of simulated spectra as shown at the bottom of FIG. 4. In general, for the reconstruction, the general form of the structure is known and some parameters are assumed from knowledge of the process by which the structure was made, leaving only a few parameters of the structure to be determined from the scatterometry data. Such a scatterometer may be configured as a normal-incidence scatterometer or an oblique-incidence scatterometer, for example.

It is often desirable to be able computationally determine how a patterning process would produce a desired pattern on a substrate. Computational determination may comprise simulation and/or modeling, for example. Models and/or simulations may be provided for one or more parts of the manufacturing process. For example, it is desirable to be able to simulate the lithography process of transferring the patterning device pattern onto a resist layer of a substrate as well as the yielded pattern in that resist layer after development of the resist, simulate metrology operations such as the determination of overlay, and/or perform other simulations. The objective of a simulation may be to accurately predict, for example, metrology metrics (e.g., overlay, a critical dimension, a reconstruction of a three dimensional profile of features of a substrate, a dose or focus of a lithography apparatus at a moment when the features of the substrate were printed with the lithography apparatus, etc.), manufacturing process parameters (e.g., edge placements, aerial image intensity slopes, sub resolution assist features (SRAF), etc.), and/or other information which can then be used to determine whether an intended or target design has been achieved. The intended design is generally defined as a pre-optical proximity correction design layout which can be provided in a standardized digital file format such as GDSII, OASIS or another file format.

Simulation and/or modeling can be used to determine one or more metrology metrics (e.g., performing overlay and/or other metrology measurements), configure one or more features of the patterning device pattern (e.g., performing optical proximity correction), configure one or more features of the illumination (e.g., changing one or more characteristics of a spatial/angular intensity distribution of the illumination, such as change a shape), configure one or more features of the projection optics (e.g., numerical aperture, etc.), and/or for other purposes. Such determination and/or configuration can be generally referred to as mask optimization, source optimization, and/or projection optimization, for example. Such optimizations can be performed on their own, or combined in different combinations. One such example is source-mask optimization (SMO), which involves the configuring of one or more features of the patterning device pattern together with one or more features of the illumination. The optimizations may use the parameterized model described herein to predict values of various parameters (including images, etc.), for example.

In some embodiments, an optimization process of a system may be represented as a cost function. The optimization process may comprise finding a set of parameters (design variables, process variables, etc.) of the system that minimizes the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics. The cost function can also be the maximum of these deviations (i.e., worst deviation). The term “evaluation points” should be interpreted broadly to include any characteristics of the system or fabrication method. The design and/or process variables of the system can be confined to finite ranges and/or be interdependent due to practicalities of implementations of the system and/or method. In the case of a lithographic projection apparatus, the constraints are often associated with physical properties and characteristics of the hardware such as tunable ranges, and/or patterning device manufacturability design rules. The evaluation points can include physical points on a resist image on a substrate, as well as non-physical characteristics such as dose and focus, for example.

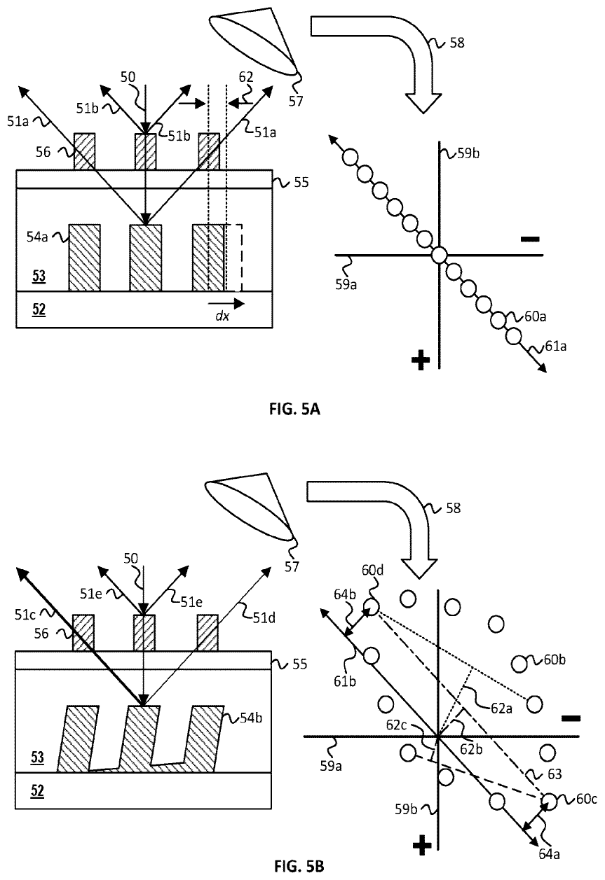

FIG. 5A illustrates operation of an additional example metrology apparatus (tool) MT, such as a diffraction-based overlay measurement tool, for overlay measurement. MT comprises a narrow band (e.g., laser light) radiation projector which projects incident radiation 50 onto a substrate 52 patterned with multiple layers. The substrate includes a target structure which comprises a buried or first grating 54a in a first layer 53. The substrate further includes one or more additional layer 55 and a top or second grating 56. The second grating 56 can be exposed, or buried, and can correspond to a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching). The incident radiation 50 is diffracted by the first grating 54a and the second grating 56, producing diffracted radiation 51a (corresponding to the first grating 54a) and diffracted radiation 51b (corresponding to the second grating 56). The reflected or scattered radiation is passed to an optical radiation detector 57, which measures optical symmetry of the reflected radiation. Optical symmetry refers to a measurement of amplitude intensity as a function of wavelength of incident radiation and/or as a function of position or location of incident radiation. Optical symmetry contains information about the relative position of the first grating 54a and the second grating 56. The amplitude asymmetry of the diffracted light, where the amplitude asymmetry is the difference between the intensity of the positive first order diffraction and the negative first order diffraction, is plotted or otherwise analyzed 58, where information from each wavelength is plotted as a function of amplitude asymmetry for the positive first order diffraction 59b and the negative first order diffraction 59a. From amplitude asymmetry, such as points 60a on a fitted line 61a, a measure of overlay is determined. The overlay can be an offset 62 between the first grating 54a and the second grating 56, such as one that corresponds to a CD for an element on the substrate 52. From this data, the structure or profile giving rise to the diffracted radiation may be reconstructed by a processing unit, e.g., by Rigorous Coupled Wave Analysis and non-linear regression. In general, for the reconstruction, the general form of the structure is known and some parameters are assumed from knowledge of the process by which the structure was made, leaving only a few parameters of the structure, such as overlay, to be determined from the diffraction data.

FIG. 5B illustrates operation of the additional example metrology apparatus MT for overlay measurement with target structure asymmetry. The substrate includes a target structure which comprises an buried asymmetric or first asymmetric grating 54b. The incident radiation 50 is diffracted by the first asymmetric grating 54b and the second grating 56, producing diffracted radiation 51c and 51d (corresponding to the first asymmetric grating 54b) and diffracted radiation 51e (corresponding to the second grating 56). The relative amplitude and phase of the diffraction radiation (e.g., diffracted radiation 51c and 51d) is affected by the asymmetry of the first asymmetric grating 54b. The first asymmetric grating incudes an asymmetric contribution to overlay metrology, which distorts both phase and amplitude of the diffracted radiation. The bottom grating asymmetry (BGA) (e.g., that of the first asymmetric grating 54b) can be given by Equations 1a and 1b, below:

$$( B - Δ B ) {e}^{i ( {β}_{0} - β )} \qquad ( 1 a )$$

$$( B - Δ B ) {e}^{i ( {β}_{0} - β )} \qquad ( 1 b )$$

where B is the amplitude of the diffraction order from the bottom grating, ΔB is the amplitude distortion of the diffraction order from the bottom grating (e.g., the first asymmetric grating 54b), β is the phase of the diffraction order from the first asymmetric grating 54b, and Δβ is the phase distortion of the diffraction order from the first asymmetric grating 54b. Likewise, T can be used to represent the amplitude of the diffraction order from the top grating (e.g., the second grating 56) and t can be used to represent the phase of the diffraction order from the top grating.

The amplitude asymmetry of the diffracted light is plotted or otherwise analyzed 58, where information from each wavelength is plotted as a function of amplitude asymmetry for the positive first order diffraction and the negative first order diffraction. Because of asymmetry on the wafer 52, points 60b do not (or may not, depending on the nature of the asymmetry) fall on a fitted line, and a measure of overlay is determined based on a distance-to-origin (e.g., distance-to-origin 62a, 62b, and 62c). The distance-to-origin is a measure of the distance from a line fitted between two points 60b of the asymmetric amplitude measurement to the (0,0) point, or origin, of the asymmetric amplitude. The distance-to-origin is related to the overlay, where the overlay can be determined using Equation 2, below, and distance-to-origin is defined using Equation 3, below:

$$Overlay = \frac{Δ {A}_{λ 2} - Δ {A}_{λ 1} - {K}_{λ 1} Δ {OVL}_{λ 1} - {K}_{λ 2} Δ {OVL}_{λ 2}}{{K}_{λ 1} - {K}_{λ 2}} + OVL \qquad ( 2 )$$

$$DTO = \frac{{K}_{λ 1} Δ {A}_{λ 2} - {K}_{λ 2} Δ {A}_{λ 1} - {K}_{λ 1} {K}_{λ 2} ( Δ {OVL}_{λ 2} - Δ {OVL}_{λ 1} )}{{K}_{λ 1} - {K}_{λ 2}} \qquad ( 3 )$$

where ΔA is the amplitude asymmetry for each of the measure wavelengths λ1 and λ2, OVL is the unperturbed layer-to-layer shift for each of the measure wavelengths λ1 and λ2, K is the overlay sensitivity for each of the measure wavelengths λ1 and λ2 and ΔOVL is the overlay caused by the phase asymmetry. For the example distance-to-origin 62a, point 60c corresponds to λ1 while point 60d corresponds to λ2 and line 63 connects the points 60c and 60d. The separation 64a of the point 60c from the line 61b (i.e., the symmetric amplitude line) is given by ΔA_{λ1}-K_{λ1}ΔOVL_{λ1}, while the separation 64b of the point 60d from the line 61b is given by ΔA_{λ2}-K_{λ2}ΔOVL_{λ2}, where the values of the separation (and their component values) can be positive or negative. The phase asymmetry-caused overlay shift ΔOVL is related to grating pitch using Equation 4, below:

$$Δ OVL = \frac{Δ β}{2 π} * a \qquad ( 4 )$$

where a is the grating pitch. The overlay sensitivity K is related to overlay and amplitude using Equation 5, below:

$$K = \frac{A}{OVL} \qquad ( 5 )$$

where A is the amplitude.

From this data, include overlay data, the structure or profile giving rise to the diffracted radiation may be reconstructed by a processing unit, e.g., by Rigorous Coupled Wave Analysis and non-linear regression. However, the asymmetry of the first asymmetric grating 54b causes dispersion of the points 60b of the asymmetric amplitude, which also causes variation in the distance-to-origin as the points 60b do not fall on a single line. Various approaches are used to correct distance-to-origin or overlay determinations based on variability and nonlinearity in asymmetric amplitude.

In a model-based approach, simulation software can be used to create a set of perturbations of a target structure, including asymmetric perturbation, where the target structure includes one or more gratings. Distance-to-origin is then modeled or otherwise calculated (e.g., determined using a linear regression) for each of the set of perturbations and a conversion matrix can be generated for the relationship between measured distance-to-origin (DTO) and one or more perturbation parameter. Perturbation parameters can include critical distance (or another measure of overlay, such as overlay error) and target structure perturbations, including side wall angle for a grating, floor tilt for one or more layer, spacing distances for a grating or other periodic structure, etc. Using the model-based approach, measured DTO can be used to identify one or more perturbation parameter value accounts for some asymmetries, such as by using Equations 6, below:

$$( \begin{matrix}{DTO}_{TE} \\ {DTO}_{TM}\end{matrix} ) * {S}_{DTO}^{- 1} = ( \begin{matrix}Δ CD \\ Δ SWA\end{matrix} ) \qquad ( 6 )$$

where DTO_{TE} and DTO_{TM} are distance-to-origin values measured for transverse electric (TE) and transverse magnetic (TM) polarized optical waves, respectively, S_{DTO} is a conversion matrix, ΔCD is a perturbation in critical distance (CD) and ΔSWA is a perturbation in side wall angle (SWA). Then a correction to the measure of overlay (i.e., either a measure of overlay or a measure of overlay error) can be determined using the perturbation parameter value, as shown in Equation 7, below:

$$( \begin{matrix}Δ CD \\ Δ SWA\end{matrix} ) * {S}_{OV} = ( \begin{matrix}Δ {OV}_{TE} \\ Δ {OV}_{TM}\end{matrix} ) \qquad ( 7 )$$

where ΔOV_{TE} and ΔOV_{TM} are the overlay correction factors for the TE and TM polarized measurements, respectively.

A measurement-based approach can also be used to correct overlay, based on multiple types of targets or target structures, calibrated over multiple sites over a portion of the wafer. The measurement-based approach generates a calibration constant C which is used to correct measures of overlay for a target structure, as shown in Equations 8 and 9, below:

$${OV}_{real , i} = {OV}_{meas T 1 , i} + {C}_{T 1} * Δ {A}_{meas T 1 , i} \qquad ( 8 )$$

$${OV}_{real , i} = {OV}_{meas T 2 , i} + {C}_{T 2} * Δ {A}_{meas T 2 , i} \qquad ( 9 )$$

where T1 and T2 represent two different target types or target structures, where OV_{meas,i} is the measured overlay for the ith location of the target type (i.e., T1 or T2), ΔA_{meas,i} is the measured amplitude asymmetry at the ith location, and C is a calibration constant for the target type.

The linear corrections to overlay measurements can be summarized by Equation 10, below:

$${OVL}_{corrected} = {OVL}_{measured} + {OVL}_{correction} = {OVL}_{measured} + C \times {DTO}_{measured} \qquad ( 10 )$$

where OVL_{corrected} represents the corrected measure of overlay (or overlay error) between two layers of the target structure, OVL_{measured} represents the measured measure of overlay between two layers of the target structure based on the asymmetric amplitudes and assuming no asymmetry is present, OVL correction represents a linear adjustment to the measure of overlay, C represents a correction factor, and DTO_{measured} represented a DTO measured from asymmetric amplitude measurements and an approximated linear fit of the asymmetric amplitude of various wavelengths which comprise the measurement. However, multiple asymmetries can generate one or more non-linear relationship between DTO and a measure of overlay.

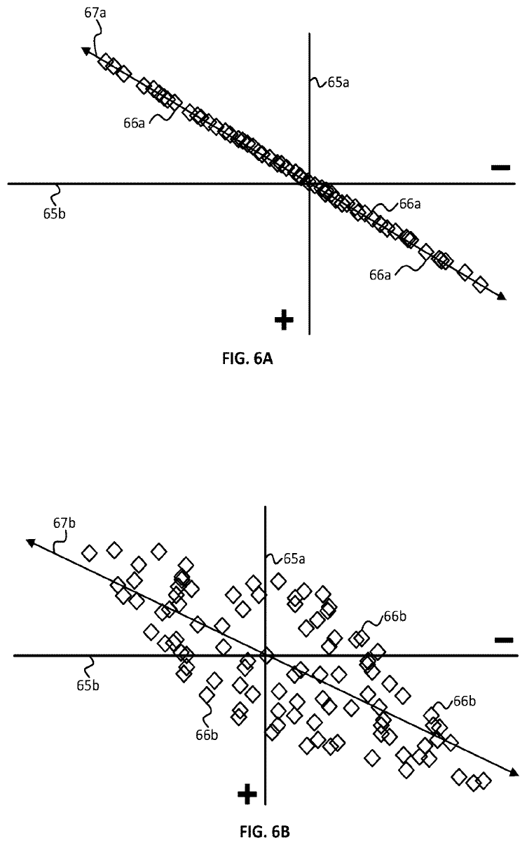

FIG. 6A illustrates an example asymmetric amplitude graph for a first example target structure for determining a measure of overlay. FIG. 6A is a graph of the amplitude intensity of the first positive diffraction, plotted along a y-axis 65a, versus the amplitude intensity of the first negative diffraction, plotted along an x-axis 65b, for each of multiple wavelengths corresponding to one of the multiple points 66a for a first example target structure. The first example target structure is a target structure with a first or buried grating and a second or top grating, where the buried grating is perturbed in one variable—side wall angle (SWA). The multiple points 66a are linearly fitted by a line 67a. As the linear fit of the multiple points 66a is relatively well correlated (R²=0.9999 in this example), the measure of overlay for the target structure can be determined from the line 67a (i.e., from the DTO of the line 67a.

FIG. 6B illustrates an example asymmetric amplitude graph for a first example target structure for determining a measure of overlay. FIG. 6B is a graph of the amplitude intensity of the first positive diffraction, plotted along a y-axis 65a, versus the amplitude intensity of the first negative diffraction, plotted along an x-axis 65b, for each of multiple wavelengths corresponding to one of the multiple points 66b for a second example target structure. The second example target structure is a target structure with a first or buried grating and a second or top grating, where the buried grating is perturbed in two variables—side wall angle (SWA) and floor tilt. The multiple points 66b are linearly fitted by a line 67b. However, in this case, the linear fit of the multiple points 66b is not relatively well correlated (R²=0.5426 in this example), the measure of overlay for the target structure determined from the DTO of the line 67b is likely to correlate to larger error and larger uncertainty.

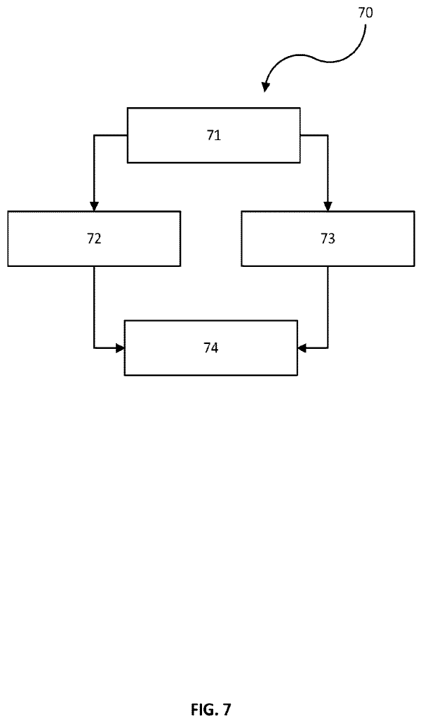

FIG. 7 illustrates a summary of operations of a present method 70 for determining a measure of overlay corrected for asymmetric target structure that can be used with manufacturing systems (e.g., manufacturing systems such as those shown in FIGS. 5, 4, 3, 2, and/or 1). At an operation 71, an electromagnetic measurement for at least one target structure is acquired. At an operation 72, a measure of overlay for the target structure is determined, based on the electromagnetic measurement and a presumption that the target structure is symmetrical. At an operation 73, a correction to the measure of overlay for the target structure is determined, based on the electromagnetic measurement, by a trained neural network. At an operation 74, a total corrected measure of overlay for the target structure is determined, based on the measure of overlay and the correction to the measure of overlay. Each of these operations is described in detail below. The operations of method 70 presented below are intended to be illustrative. In some embodiments, method 70 may be accomplished with one or more additional operations not described, and/or without one or more of the operations discussed. Additionally, the order in which the operations of method 70 are illustrated in FIG. 7 and described below is not intended to be limiting. In some embodiments, one or more portions of method 70 may be implemented (e.g., by simulation, modeling, etc.) in one or more processing devices (e.g., one or more processors). The one or more processing devices may include one or more devices executing some or all of the operations of method 70 in response to instructions stored electronically on an electronic storage medium. The one or more processing devices may include one or more devices configured through hardware, firmware, and/or software to be specifically designed for execution of one or more of the operations of method 70, for example.

As described above, method 70 (and/or the other methods and systems described herein) is configured to provide a generic framework to determination of a measure of overlay. The electromagnetic data are assumed to be present in the form of asymmetric amplitude ratios for a set of electromagnetic wavelengths, or in the form of distance-to-origin values for a pair of wavelengths. In method 70, a measure of asymmetry (e.g., which may, in some embodiments, be a measure of distance-to-origin, an asymmetric intensity ratio, asymmetric intensity difference, offset angle, and/or offset angle difference based on the asymmetric amplitude for two or more wavelengths, etc.) is determined from a manufacturing system (e.g., a diffraction-based system). The measure of asymmetry is determined based on the asymmetric amplitude ratio between a positive first order diffraction and a negative first order diffraction for radiation diffracted by the target structure. Based on the measure of asymmetry, one or more measure of overlay is determined. The measure of overlay corresponds to the relative locations on the substrate of two gratings but may also be determined based on the relative locations of other structures, including other periodic structures, or by using scatterometry, including interferometry scatterometry, or by image based (e.g., scanning electron microscopy (SEM) image-based, optical image based, etc.) methods. The measure of overlay (e.g., which may, in some embodiments, be a measure of overlay error, a measure of overlay, an overlay angle, a critical distance (CD), and may correspond to overlay in one or more dimension or direction, etc.) allows for adjustment, monitoring, and/or calibration of one or more process step or element for the manufacturing process. By accounting asymmetry in the target structure, the calculation of the measure of overlay can be improved in accuracy and certainty and process control therefore also improved.

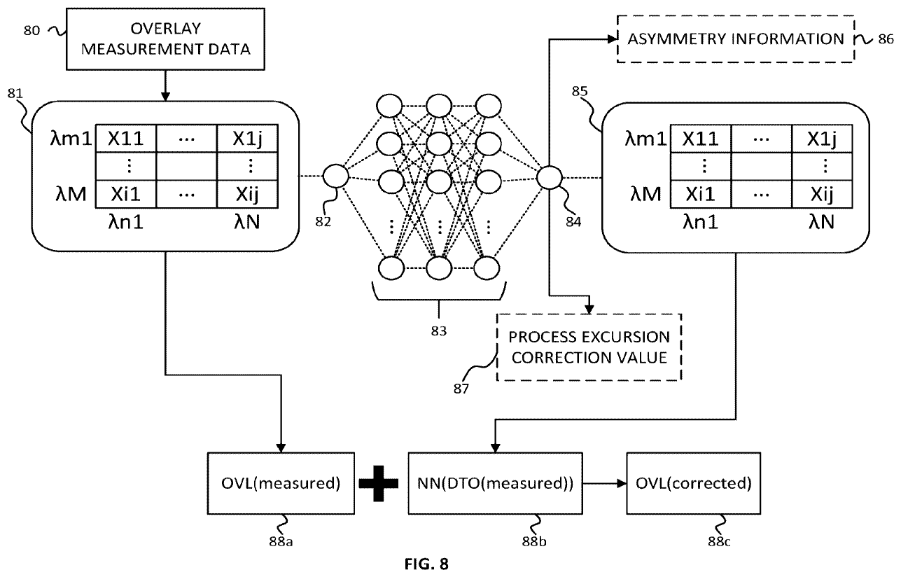

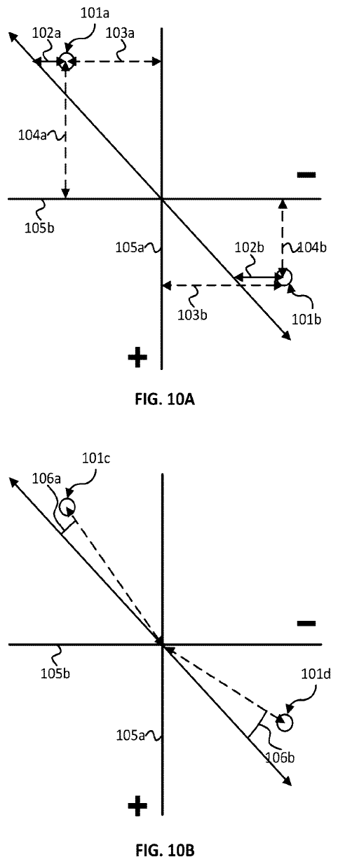

FIG. 8 illustrates a diagram for determining a corrected measure of overlay for target structure accounting for target structure asymmetry using a neural network according to an embodiment of the present disclosure. Overlay measurement data 80 is collected using an optical, or other electromagnetic, measurement apparatus, such as those described in reference to FIGS. 4 and/or 5. The overlay measurement data 80 includes measurement of amplitude, phase, polarity, and/or location, for scatter, diffracted, or reflected radiation corresponding to a target structure on a wafer. For each wavelength, an asymmetric amplitude is determined based on the relationship between the amplitude of the positive first order diffraction and the amplitude of the negative first order diffraction. In some embodiments, higher order diffractions can be used. Additionally, in some embodiments, other information can be used instead of or in addition to amplitude, such as phase, polarity, etc. At least one pair of wavelengths is selected from the overlay measurement data 80 and based on the asymmetric amplitude (or another measure of intensity) of the pair of wavelengths, a distance-to-origin (DTO) value is determined. The DTO measures the distance from a line comprising the asymmetric amplitude of each of the pair of wavelengths to the origin of the asymmetric amplitude graph. Other measurements can be used instead of DTO, some of which will be described in reference to FIGS. 10A-10B. Based on the DTO for at least two wavelengths an input or feature vector 81 is determined. The feature vector 81 contains at least two wavelengths together with a measure of asymmetry corresponding to a pair of wavelengths. The feature vector 81 can contain information corresponding to multiple wavelengths, where each wavelength can be used to determine a measure of asymmetry (i.e., DTO) with respect to each other wavelength. The number of wavelengths used to determine the feature vector 81 can be a function of process step or layer for which the measure of overlay is being determined. Acquiring overlay measurement data 80 at a wavelength can be a time-consuming process, as many target structures on the wafer are measured, and as the metrology apparatus can require adjustment (e.g., target location adjustment, wavelength detection apparatus adjustment, etc.) for each of the various wavelengths for which data is acquired. Thus, the size of the feature vector 81 can be selected to balance uncertainty and accuracy needs with throughput needs. For example, for layers which define a CD measurement may be acquired at more wavelengths for a larger feature vector, while for other layers, a smaller feature vector can be used. Uncertainty may be reduced with selection of a larger feature vector, but in some cases uncertainty and accuracy may be limited by material properties and not significantly improved with larger feature vectors.

The feature vector 81 is depicted as containing a set of measures of asymmetry (i.e., x11, . . . , xi1, . . . , x1j, . . . , xij) in a matrix, which correspond to pair of wavelengths which contain a set of first wavelengths λm1 to λM in the first dimension and to a set of second wavelengths λn1 to λN in the second dimension. The input is represented as a matrix for visual simplicity, but can be any appropriate data storage structure, including a vector, a feature value, etc. The set of first wavelengths (i.e., λm1 to λM) can be the same as the set of second wavelengths (i.e., λn1 to λN), or can contain different wavelengths. Multiple wavelengths are included in the feature vector 81—if only one wavelength pair is used a measure of asymmetry input can map to multiple corrections to the measure of overlay values (i.e., the function is not well-defined). The pairs of wavelengths included in the feature vector 81 need not comprise all of the possible wavelength pairs in the overlay measurement data. For example, if wavelengths (λ1, λ2, λ3, λ4) are measured, the feature vector can comprise DTO determined for the wavelength pairs (λ1, λ2), (λ1, λ3), and (λ1, λ4) and may not comprise the DTO determined for the wavelength pair (λ2, λ3) (λ2, λ4), and (λ3, λ4). Further, DTO is independent of the order of the wavelength pair and thus DTO of wavelength pair (λ1, λ2) is the same as the DTO of a wavelength pair (λ2, λ1). The wavelengths which comprise the feature vector 81 can also depend on the material and manufacturing steps which comprise the various layers of the target structure. For example, wavelengths which are absorbed by a layer of the target structure may not excluded for use in the feature vector 81. The sensitivity of the relationship between DTO and a measure of overlay varies between wavelengths—therefore wavelengths in which a measure of asymmetry (i.e., DTO) is more sensitive to changes in a measure of overlay can be preferentially selected for the feature vector 81. The feature vector 81 elements, size, and components can be further refined or selected through appropriate feature engineering.

The feature vector 81 is input into a trained neural network. The neural network can be any type of neural network, such as a fully connected neural network, a convolutional neural network, or other type or neural network, and in some cases can be another class of machine learning model including multi-variable regression model. In FIG. 8, a fully connected neural network model is shown, but this should be understood to be an example only and not limiting on model selection. The neural network contains an input layer 82, one or more hidden layers 83, and an output layer 84. The output 85 of the neural network is a correction to the measure of overlay for each of the wavelength pairs of the input which accounts for asymmetry. The output 85 can also include one or more process excursion value 87 for a neural network trained to output processes excursion values 87. Process excursion values 87, such as layer thickness, CD variation, etc., can be correlated or related to measured intensities and as DTO (and other measures of asymmetry) are a function of intensity, process excursion values 87 can also be determined by a trained neural network based on a feature vector 81 comprising DTO values. The neural network can output both corrections to the measure of overlay and process excursion values 87. Additionally, in one or more embodiment, the trained neural network can output asymmetry information 86, such as a conformation or target structure perturbation identification. The neural network can be trained to correlate the feature vector 81 with a target structure or a perturbation of the target structure. In such a case, the neural network would be trained with a set of training data which also includes target structure perturbation information, such as conformation. Successful training for the neural network to identify a perturbation of the target structure could require larger feature vectors and can be restricted to processes with smaller amount of naturally occurring variation.

For each pair of wavelengths which correspond to a measure of asymmetry, a measure of overlay 88a is calculated based on the measure of asymmetry (as measured) and based on an assumption that target structure asymmetry is negligible (i.e., asymmetry is ignored). For each pair of wavelengths which correspond to a measure of asymmetry, a measure of correction 88b is also determined based on the measure of asymmetry input into the trained neural network. The final value of overlay 88c is the sum of the measure of overlay based on the as-measures measure of asymmetry and the correction to the measure of overlay output by the trained neural network. This method can therefore account for perturbation in multiple perturbation parameters of a target structure, where the relationship between the measure of asymmetry and the measure of overlay is nonlinear. In some embodiments, the trained neural network can output a correction to the measurement of overlay, but it should be understood that in other embodiments the trained neural network can output the corrected measurement of overlay instead.

A trained neural network can further determine that a measure of asymmetry indicates that the target structure is not asymmetric, and return either a correction to the measurement of overlay that is a zero or null value or output a response that the neural network portion of the determination of the measurement of overlay is not needed. The training of the neural network can depend on the complexity of the target structure, its layers, and/or the stack structure for the wafer. The trained neural network can further indicate a confidence interval or uncertainty interval. In some embodiments, the trained neural network, based, for example, on the confidence interval, uncertainty interval, or a process excursion value, can indicate that retraining should be initiated. In other cases, the neural network can be retrained following changes to the target structure, stack structure, or significant manufacturing changes or retooling.

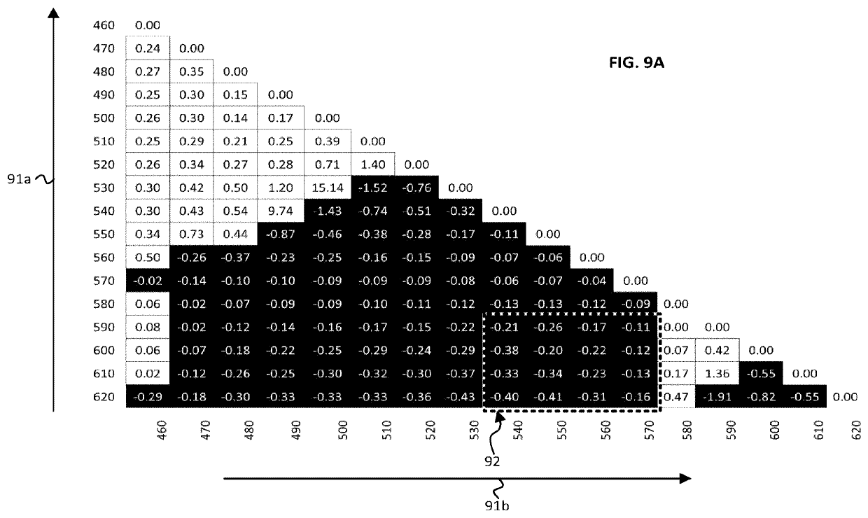

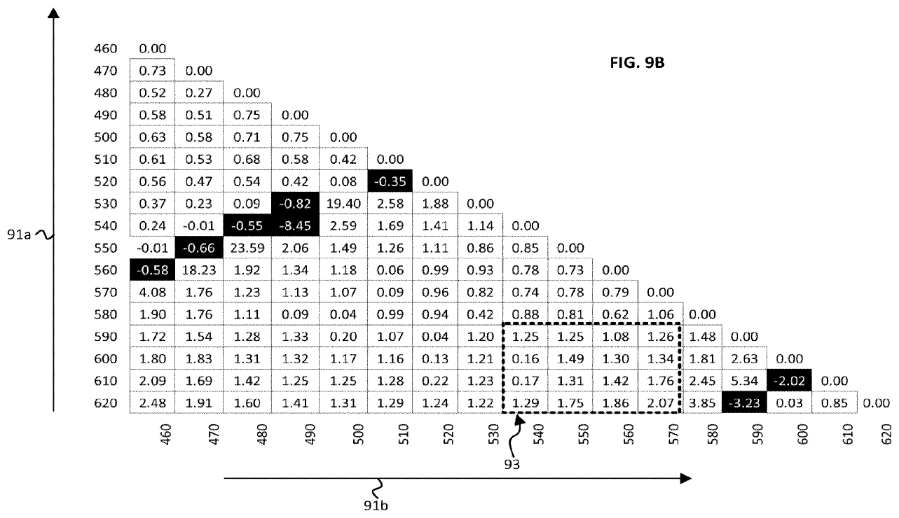

FIG. 9A illustrates measures of asymmetry determined for an example target structure. FIG. 9A depicts a table containing values of the set of first wavelengths (along y-axis 91a) and values of the set of the second wavelengths (along x-axis 91b). For each wavelength pair, a value of DTO is shown, although a different measure of asymmetry can be used as will be discussed in reference to FIGS. 10A-10B. The values are displayed in a heat map, with values smaller than 0.1 displayed in black boxes and values greater that 0.1 displayed in white boxes. Because DTO is symmetric with respect to the order of the pair of wavelengths, only the lower half of the table is shown. The table displays the values of DTO for a specific perturbation of a specific target structure. A set of values corresponding to the training data selected for the neural network is surrounded by the box 92. The training data for the neural network can comprise all or less than all wavelength pairs simulated or measured for a perturbation. The training data, and the feature vectors of the training data, can vary based on target structure material, manufacturing processes, reliability, etc. The wavelengths selected for the training data and/or the feature vector can be limited or predetermined based on time constraints, material constraints, etc. or can be included because of metrology apparatus and other material constraints, limitations and ranges. In some instances, metrology wavelengths can lie between 400 nm and 900 nm.

FIG. 9B illustrates example corrections to a measure of overlay determined for an example target structure, according to an embodiment. FIG. 9B depicts a table containing values of the set of first wavelengths (along y-axis 91a) and values of the set of the second wavelengths (along x-axis 91b). For each wavelength pair, a correction to a value of overlay error (OVL) is shown, although a different measure of overlay can be used. The values are displayed in a heat map, with values smaller than 0.1 displayed in black boxes and values greater that 0.1 displayed in white boxes. Because OVL is also symmetric with respect to the order of the pair of wavelengths, only the lower half of the table is shown. The table displays the correction to values of overlay error for a specific perturbation of a specific target structure as a function of wavelength. A set of values corresponding to the training data selected for the neural network, i.e., the training data found in box 93 in FIG. 9A, is surrounded by the box 93. For each of the output values, the as-measured measure of overlay error (which is dependent on the identify of each wavelength of the DTO determination) can be corrected to account for target structure asymmetry.

FIGS. 10A-10B illustrate determinations of various measures of asymmetry, according to an embodiment. Although distance-to-origin is used herein, it should be understood that the measure of asymmetry can be instead another measure of amplitude asymmetry for a wavelength pair. FIG. 10A depicts an example graph where the amplitude asymmetry for a first wavelength is plotted at a point 101a, and the amplitude asymmetry for a second wavelength is plotted at a point 101b, with respect to the amplitude intensity of the first positive diffraction, plotted along a y-axis 105a, and the amplitude intensity of the first negative diffraction, plotted along an x-axis 105b. An asymmetric intensity ratio can be determined based on a ratio of the intensities measured for the pair of wavelengths. This can be determined by the ratio of the distances 102a and 102b which separate the asymmetric amplitudes from the line representing symmetric amplitudes. An asymmetric intensity difference can also be determined based on a difference of the intensities measured for the pair of wavelengths. This can be determined by the difference of the distances 102a and 102b which separate the asymmetric amplitudes from the line representing symmetric amplitudes. Other measures of asymmetry can be determined based on the relative amplitude of the first positive diffraction for each of the wavelengths (i.e., amplitude 104a for the point 101a and amplitude 104b for the point 101b) and the first negative diffraction for each of the wavelengths (i.e., amplitude 103a for the point 101a and amplitude 103b for the point 101b).

FIG. 10B depicts an example graph where the amplitude asymmetry for a first wavelength is plotted at a point 101c, and the amplitude asymmetry for a second wavelength is plotted at a point 101d. An offset angle can be determined based on the angle of deviation from the symmetric diagonal of the line from the origin point of the plot to each of the points (i.e., 101c and 101d) corresponding to the wavelengths of the pair. Thus, the point 101c corresponds to an angle 106a while the point 101d corresponds to an angle 106b. Further, an offset angle difference can be determined based on the difference between the angle 106a and the angle 106b. These measures of asymmetry, i.e., the asymmetric intensity ratio, the asymmetric intensity difference, the offset angle, and/or the offset angle difference, can be used in addition to or instead of DTO, where DTO is the distance-to-origin as previously defined. In addition, other appropriate measures of asymmetry can be determined and used as inputs to a corresponding trained neural network, where a measure of asymmetry depends on an asymmetric intensity for two or more wavelengths.

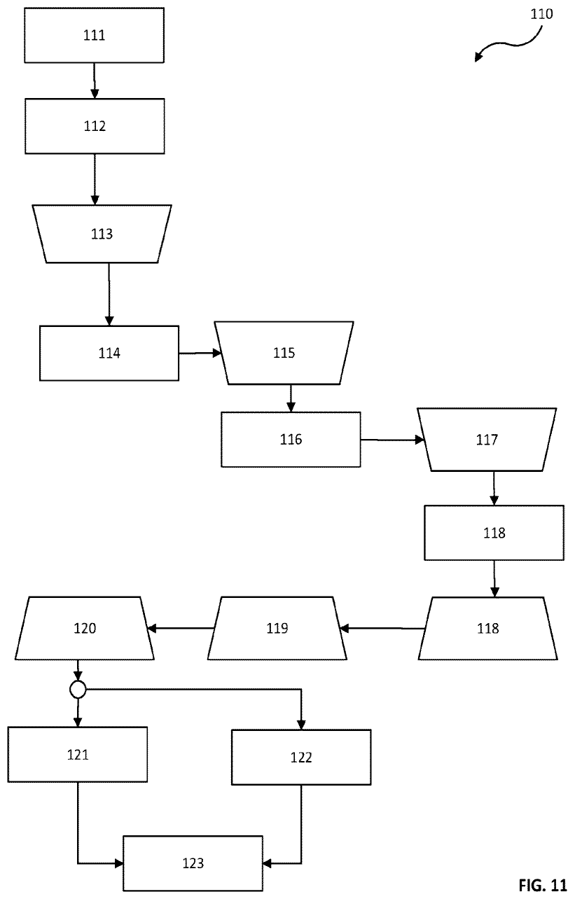

FIG. 11 illustrates a exemplary method 110 for generating training data for a neural network (e.g., to produce a trained neural network such as that shown in FIG. 8). Training data can be acquired from measurement data for a target structure, where such measurement data includes both measures of asymmetry for multiple wavelengths and measures of overlay for multiple wavelengths. As traditional measures of overlay do not account for asymmetry, acquiring training data from production wafers or fabricated target structures can require intensive measurement (for example, cross-sectional SEM measurements and other in depth and destructive analytics) to determine an accurate measure of overlay. In some embodiments, therefore, multiple perturbations of a target structure are modeled or otherwise simulation. At an operation 111, a target structure is selected. The target structure can comprise multiple layers and multiple gratings which produce diffractions. At an operation 112, a set of perturbation parameters is selected. The perturbation parameters can include various layer thicknesses, side wall angle (SWA), floor tilt, etc. for each of the layers of the target structure. The set of perturbation parameters can be selected based on production and process knowledge, based on expected variation in processes and layers, based on previously detected asymmetries, etc. For each of the set of perturbation parameters, a range for the value of the perturbation parameter is determined. Based on a number of points or an incrementation size, a number of values of the perturbation parameter are selected for the range. At operation 113, a first perturbation parameter is selected and based on the range and incrementation size for the first perturbation parameter, a number of first perturbations is determined. At operation 114, a perturbation of the target structure is generated for each point in the range. In some cases, the range can be discontinuous or the incrementation size otherwise variable.

At operation 115, a second perturbation parameter is selected and based on the range and incrementation size for the second perturbation parameter, a number of second perturbations is determined. At operation 116, perturbations of the target structure are generated for each point in the range for each of the perturbations of the target structure from the first perturbation parameter.

These operations can continue for each of the set of perturbation parameters, such that at operation 117, a n^{th} perturbation parameter is selected and based on the range and incrementation size for the nth perturbation parameter a number of nth perturbations is determined. At operation 118, perturbations of the target structure are generated for each point in the range for each of the perturbations of the target structure produced by the (n−1) previous perturbations of the target structure.

At operation 118, the set of perturbations of the target structure are compiled for the nth perturbation. Likewise, at operation 119, the set of perturbations of the target structure are compiled for each of the values of the second perturbation parameter. At operation 120, the set of perturbations of the target structure are compiles for each of the values of the first perturbation parameter.

At operation 121 a measure of asymmetry is determined for the full set of perturbations of the target structure. The measure of asymmetry can be determined based on any appropriate model, or simulation, including an optical model. At operation 122, a measure of overlay is determined for the full set of perturbations of the target structure. The measure of overlay, where overlay may or may not be included as a perturbation parameter, can be determined from the simulated or model target structure. At operation 123, training data is generated based on the set of perturbations together with their measures of asymmetry and measures of overlay. For example, a feature vector can be determined based on the simulated measure of asymmetry for multiple wavelengths and a supervisory signal can be determined based on the measure of overlay. A neural network or other machine learning model can then be trained to identify a measure of overlay based on a measure of asymmetry. Another appropriate method of perturbation generation, such as generation of a target structure with multiple perturbations at one time, can also be employed.

The operations of method 110 presented below are intended to be illustrative. In some embodiments, method 110 may be accomplished with one or more additional operations not described, and/or without one or more of the operations discussed. Additionally, the order in which the operations of method 110 are illustrated in FIG. 11 and described below is not intended to be limiting. In some embodiments, one or more portions of method 110 may be implemented (e.g., by simulation, modeling, etc.) in one or more processing devices (e.g., one or more processors). The one or more processing devices may include one or more devices executing some or all of the operations of method 110 in response to instructions stored electronically on an electronic storage medium. The one or more processing devices may include one or more devices configured through hardware, firmware, and/or software to be specifically designed for execution of one or more of the operations of method 110, for example.

As described above, method 110 (and/or the other methods and systems described herein) is configured to provide a generic framework for generating training data for a neural network in order to identify a measure of overlay based on a measure of asymmetry. The electromagnetic data are assumed to be present in the form of asymmetric amplitude ratios for a set of electromagnetic wavelengths, or in the form of distance-to-origin values for a pair of wavelengths. In method 110, a measure of asymmetry (e.g., which may, in some embodiments, be a measure of distance-to-origin, an asymmetric intensity ratio, asymmetric intensity difference, offset angle, and/or offset angle difference based on the asymmetric amplitude for two or more wavelengths, etc.) is determined from a modeling system (e.g., a diffraction-based system). The measure of asymmetry is determined based on the asymmetric amplitude ratio between a positive first order diffraction and a negative first order diffraction for radiation diffracted by the target structure. Based on the measure of asymmetry, one or more measure of overlay is determined. The measure of overlay corresponds to the relative locations on the substrate of two gratings but may also be determined based on the relative locations of other structures, including other periodic structures, or by using scatterometry modeling, including interferometry scatterometry modeling, or by image based (e.g., scanning electron microscopy (SEM) image-based, optical image based, etc.) modeling methods. The measure of overlay (e.g., which may, in some embodiments, be a measure of overlay error, a measure of overlay, an overlay angle, a critical distance (CD), and may correspond to overlay in one or more dimension or direction, etc.) is a measurement of alignment of the target structure, which is not directly dependent on buried asymmetries, or asymmetries other than to a grating, but which is affected by asymmetry within the target structure.

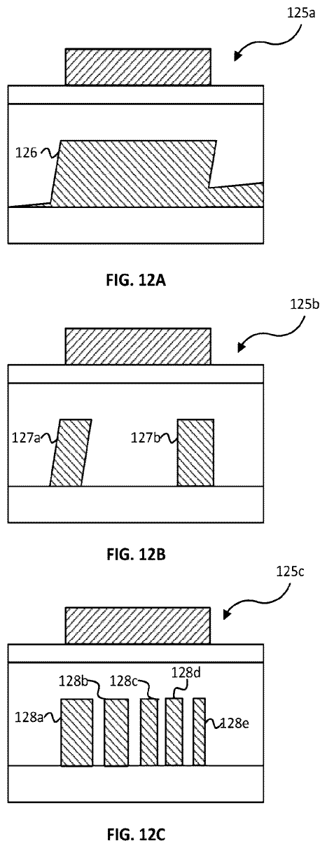

FIGS. 12A-12C illustrate example perturbations of a target structure generated for training a neural network, according to an embodiment. FIG. 12A illustrates an example target structure 125a, where an unsegmented overlay determination structure 126 exhibits side wall angle (SWA) tilt and floor tilt. FIG. 12B illustrates an example target structure 125b, where a segmented overlay determination structure 127a and 127b exhibits mandrel, spacer, and thickness variation for a self-aligned double patterning (SADP) step. FIG. 12C illustrates an example target structure 125c, where a parallel segmented overlay target 128a-128e exhibits CD imbalance. Target structures perturbations such as these can be included in training data, and perturbation parameters such as SWA, floor tilt, spacing, thickness. CD, etc. can be included in generation of perturbations of the target structure.

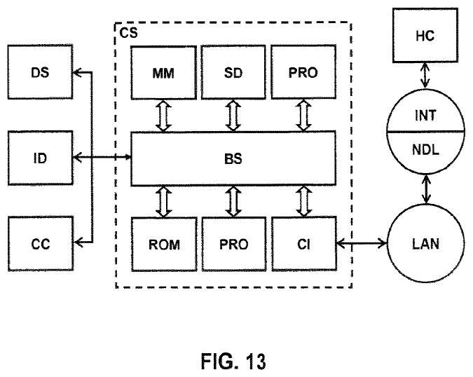

FIG. 13 is a diagram of an example computer system CS that may be used for one or more of the operations described herein. Computer system CS includes a bus BS or other communication mechanism for communicating information, and a processor PRO (or multiple processors) coupled with bus BS for processing information. Computer system CS also includes a main memory MM, such as a random-access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a cathode ray tube (CRT) or flat panel or touch panel display for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, portions of one or more methods described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” and/or “machine readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM.

Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface C1 may be a local area network (LAN) card to provide a data communication connection to a compatible LAN. Wireless links may also be implemented. In any such implementation, communication interface CI sends and receives electrical, electromagnetic, or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic, or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

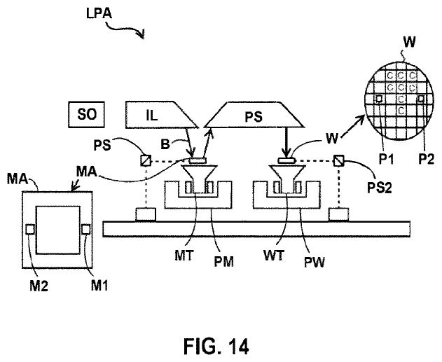

FIG. 14 is a schematic diagram of another lithographic projection apparatus (LPA) that may be used for, and/or facilitating one or more of the operations described herein. LPA can include source collector module SO, illumination system (illuminator) IL configured to condition a radiation beam B (e.g., EUV radiation), support structure MT, substrate table WT, and projection system PS. Support structure (e.g., a patterning device table) MT can be constructed to support a patterning device (e.g., a mask or a reticle) MA and connected to a first positioner PM configured to accurately position the patterning device. Substrate table (e.g., a wafer table) WT can be constructed to hold a substrate (e.g., a resist coated wafer) W and connected to a second positioner PW configured to accurately position the substrate. Projection system (e.g, a reflective projection system) PS can be configured to project a pattern imparted to the radiation beam B by patterning device MA onto a target portion C (e.g., comprising one or more dies) of the substrate W.

As shown in this example, LPA can be of a reflective type (e.g., employing a reflective patterning device). It is to be noted that because most materials are absorptive within the EUV wavelength range, the patterning device may have multilayer reflectors comprising, for example, a multi-stack of molybdenum and silicon. In one example, the multi-stack reflector has a 40 layer pairs of molybdenum and silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

Illuminator IL can receive an extreme ultraviolet radiation beam from source collector module SO. Methods to produce EUV radiation include, but are not necessarily limited to, converting a material into a plasma state that has at least one element, e.g., xenon, lithium, or tin, with one or more emission lines in the EUV range. In one such method, often termed laser produced plasma (“LPP”), the plasma can be produced by irradiating a fuel, such as a droplet, stream or cluster of material having the line-emitting element, with a laser beam. Source collector module SO may be part of an EUV radiation system including a laser (not shown in FIG. 14), for providing the laser beam exciting the fuel. The resulting plasma emits output radiation, e.g., EUV radiation, which is collected using a radiation collector, disposed in the source collector module. The laser and the source collector module may be separate entities, for example when a CO2 laser is used to provide the laser beam for fuel excitation. In this example, the laser may not be considered to form part of the lithographic apparatus and the radiation beam can be passed from the laser to the source collector module with the aid of a beam delivery system comprising, for example, suitable directing mirrors and/or a beam expander. In other examples, the source may be an integral part of the source collector module, for example when the source is a discharge produced plasma EUV generator, often termed a DPP source.

Illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross section.

The radiation beam B can be incident on the patterning device (e.g., mask) MA, which is held on the support structure (e.g., patterning device table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometric device, linear encoder, or capacitive sensor), the substrate table WT can be moved accurately (e.g., to position different target portions C in the path of radiation beam B). Similarly, the first positioner PM and another position sensor PS1 can be used to accurately position the patterning device (e.g., mask) MA with respect to the path of the radiation beam B. Patterning device (e.g., mask) MA and substrate W may be aligned using patterning device alignment marks M1, M2 and substrate alignment marks P1, P2.

The depicted apparatus LPA could be used in at least one of the following modes, step mode, scan mode, and stationary mode. In step mode, the support structure (e.g., patterning device table) MT and the substrate table WT are kept essentially stationary, while an entire pattern imparted to the radiation beam is projected onto a target portion C at one time (e.g., a single static exposure). The substrate table WT is then shifted in the X and/or Y direction so that a different target portion C can be exposed. In scan mode, the support structure (e.g., patterning device table) MT and the substrate table WT are scanned synchronously while a pattern imparted to the radiation beam is projected onto target portion C (i.e., a single dynamic exposure). The velocity and direction of substrate table WT relative to the support structure (e.g., patterning device table) MT may be determined by the (de) magnification and image reversal characteristics of the projection system PS. In stationary mode, the support structure (e.g., patterning device table) MT is kept essentially stationary holding a programmable patterning device, and substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

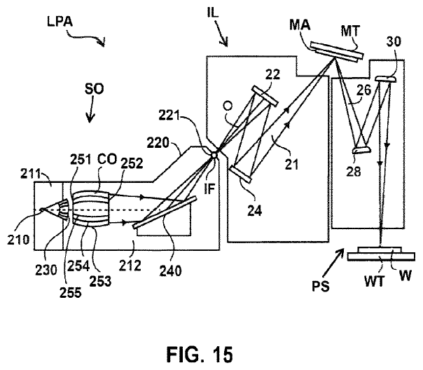

FIG. 15 is a detailed view of the lithographic projection apparatus shown in FIG. 14. As shown in FIGS. 10A-10B, the LPA can include the source collector module SO, the illumination system IL, and the projection system PS. The source collector module SO is configured such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the hot plasma 210 is created to emit radiation in the EUV range of the electromagnetic spectrum. The hot plasma 210 is created by, for example, an electrical discharge causing at least partially ionized plasma. Partial pressures of, for example, 10 Pa of Xe, Li, Sn vapor or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier trap 230 (described below) also includes a channel structure. The collector chamber 211 may include a radiation collector CO which may be a grazing incidence collector. Radiation collector CO has an upstream radiation collector side 251 and a downstream radiation collector side 252. Radiation that traverses collector CO can be reflected off a grating spectral filter 240 to be focused on a virtual source point IF along the optical axis indicated by the line “O”. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently, the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the radiation beam 21 at the patterning device MA, held by the support structure MT, a patterned beam 26 is formed and the patterned beam 26 is imaged by the projection system PS via reflective elements 28, 30 onto a substrate W held by the substrate table WT. More elements than shown may generally be present in illumination optics unit IL and projection system PS. The grating spectral filter 240 may optionally be present, depending upon the type of lithographic apparatus, for example. Further, there may be more mirrors present than those shown in the figures, for example there may be 1-6 additional reflective elements present in the projection system PS than shown in FIG. 15.

Collector optic CO, as illustrated in FIG. 15, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

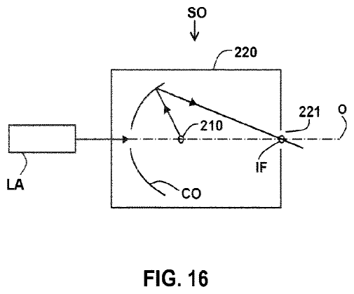

FIG. 16 is a detailed view of source collector module SO of the lithographic projection apparatus LPA (shown in previous figures). Source collector module SO may be part of an LPA radiation system. A laser LA can be arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.

The concepts disclosed herein may simulate or mathematically model any generic imaging, etching, polishing, inspection, etc. system for sub wavelength features, and may be useful with emerging imaging technologies capable of producing increasingly shorter wavelengths. Emerging technologies include EUV (extreme ultraviolet), DUV lithography that is capable of producing a 193 nm wavelength with the use of an ArF laser, and even a 157 nm wavelength with the use of a Fluorine laser. Moreover. EUV lithography is capable of producing wavelengths within a range of 20-50 nm by using a synchrotron or by hitting a material (either solid or a plasma) with high energy electrons in order to produce photons within this range.

Embodiments of the present disclosure can be further described by the following clauses.
1. A method comprising:
obtaining a measure of asymmetry, wherein the measure of asymmetry is based, at least in part, on an electromagnetic measurement of a target structure; and
determining, based at least in part on a trained machine learning model, a measure of overlay for the target structure based on the measure of asymmetry.
2. The method of clause 1, wherein the measure of overlay is an overlay error value.
3. The method of clause 1, wherein the measure of overlay is an overlay value.
4. The method of clause 1, wherein the electromagnetic measurement comprises a first electromagnetic measurement at a first wavelength and a second electromagnetic measurement at a second wavelength and wherein the measure of asymmetry is determined based on a relationship between the first electromagnetic measurement and the second electromagnetic measurement.
5. The method of clause 4, wherein the measure of asymmetry is a distance-to-origin.
6. The method of clause 5, wherein the distance-to-origin comprises a distance between a line, wherein the line is through a point corresponding to the first wavelength and a point corresponding to the second wavelength, and an origin point for a plot of asymmetric amplitude.
7 The method of clause 4, wherein the measure of asymmetry is at least one of an asymmetric intensity ratio, an asymmetric intensity difference, a set of offset angle values, an offset angle difference value, or a combination thereof.
8. The method of clause 4, wherein the measure of asymmetry is further determined based on a relationship between a third electromagnetic measurement at a third wavelength and a fourth electromagnetic measurement at a fourth wavelength.
9. The method of clause 8, wherein the third wavelength is the same as the first wavelength.
10. The method of clause 1, where in target structure comprises a first layer, and wherein the first layer comprises a diffraction grating.
11. The method of clause 10, wherein the target structure further comprises a second layer, and wherein the second layer comprise a diffraction grating.
12. The method of clause 1, wherein the electromagnetic measurement is performed by an optical metrology apparatus.
13. The method of clause 12, wherein the optical metrology apparatus is a broadband optical metrology apparatus.
14. The method of clause 12, wherein the optical metrology apparatus is an scatterometry-based metrology apparatus.
15. The method of clause 12, wherein the optical metrology apparatus is a diffraction-based metrology apparatus.
16. The method of clause 1, wherein determining, based at least in part on the trained machine learning model, the measure of overlay for the target structure comprises:
obtaining a measure of symmetric overlay for the target structure based, at least in part, on the electromagnetic measurement of the target structure:
determining, based at least in part on the trained machine learning model, a measure of asymmetry-adjusted overlay based on the measure of asymmetry; and
determining the measure of overlay for the target structure based at least in part on the measure of symmetric overlay and the measure of asymmetry-adjusted overlay.
17. The method of clause 16, wherein determining the measure of overlay for the target structure comprises determining the measure of overlay for the target structure based at least in part on a sum of the measure of symmetric overlay and the measure of asymmetric-adjusted overlay.
18. The method of clause 1, wherein determining a measure of overlay further comprises: determining if the measure of asymmetry is substantially equivalent to zero;
based on a determination that the measure of asymmetry is substantially equivalent to zero,
obtaining a measure of symmetric overlay for the target structure based, at least in part, on the electromagnetic measurement of the target structure; and
determining the measure of overlay for the target structure based at least in part on the measure of symmetric overlay.
19. The method of clause 1, further comprising:
generating training data, wherein the trained machine learning model is trained based at least in part on the training data,
wherein the training data comprises a measure of asymmetry labeled with a measure of overlay for a set of perturbations of the target structure.
20. The method of clause 19, wherein generating training data comprises generating the set of perturbations of the target structure.
21. The method of clause 20, wherein generating the set of perturbations of the target structure comprises:
determining a set of perturbation parameters; and
generating the set of perturbations of the target structure based, at least in part, on the set of perturbation parameters.
22. The method of clause 21, wherein determining the set of perturbation parameters comprises selecting the set of perturbation parameters based at least in part on the target structure.
23. The method of clause 21, wherein determining the set of perturbation parameters comprises selecting the set of perturbation parameters based at least in part on a stack structure, wherein the stack structure comprises the target structure.
24. The method of clause 21, wherein generating the set of perturbations of the target structure further comprises:
determining a first perturbation range for a value of a first perturbation parameter;
determining at least one first perturbation value for the first perturbation parameter based at least in part on the first perturbation range; and
generating the set of perturbations of the target structure based on the at least one first perturbation value of the first perturbation parameter.
25. The method of clause 24, further comprising:
determining a second perturbation range for a value of a second perturbation parameter; and
determining at least one second perturbation value for the second perturbation parameter based at least in part on the second perturbation range;
wherein the set of perturbations of the target structure is generated based on the at least one first perturbation value of the first perturbation parameter and the at least one second perturbation value of the second perturbation parameter.
26. The method of clause 19, wherein the measure of asymmetry is determined based on a simulation of the electromagnetic measurement of the set of perturbations of the target structure.
27. The method of clause 19, wherein the measure of overlay is determined based on a model of a perturbation of the target structure.
28. The method of clause 21, wherein the set of perturbation parameters comprises overlay.
29. The method of clause 21, wherein the set of perturbation parameters comprises critical distance.
30. The method of clause 1, wherein the trained machine learning model is a neural network.
31. The method of clause 1, wherein the trained machine learning model is configured to output the measure of overlay from an input, wherein the input is based at least in part on the measure of asymmetry.
32. The method of clause 1, wherein the trained machine learning model is configured to output the measure of overlay an input, wherein the input is based at least in part on the electromagnetic measurement of the target structure, and wherein obtaining the measure of asymmetry comprises determining the measure of asymmetry based at least in part on the electromagnetic measurement of the target structure.
33. The method of clause 1, further comprising determining, based at least on the trained machine learning model, a confidence interval for the measure of overlay based on the measure of asymmetry.
34. The method of clause 1, further comprising identifying, based at least in part on the trained machine learning model, a conformation of the target structure based on the measure of asymmetry.
35. The method of clause 34, further comprising:
generating training data, wherein the trained machine learning model is trained based at least in part on the training data,
wherein the training data comprises a set of perturbations of the target structure and their corresponding measures of asymmetry labeled with corresponding measures of overlay.
36. A method comprising:
generating training data, wherein generating the training data comprises,
selecting at least one perturbation of a target structure;
obtaining a measure of asymmetry corresponding to at least one perturbation of a target structure:
determining a feature vector based, at least in part, on the measure of asymmetry corresponding to the at least one perturbation of the target structure;
obtaining a measure of overlay corresponding to the at least one perturbation of the target structure;
determining a supervisory signal based, at least in part, on the measure of overlay corresponding to the at least one perturbation of the target structure; and
labeling the feature vector for the at least one perturbation of the target structure with the supervisory signal.
37. The method of clause 36, wherein selecting at least one perturbation of the target structure comprises generating the at least one perturbation of the target structure.
38. The method of clause 37, wherein generating the at least one perturbation of the target structure comprises:
determining a set of perturbation parameters; and
generating the at least one perturbation of the target structure based, at least in part, on the set of perturbation parameters.
39. The method of clause 38, wherein generating the at least one perturbation of the target structure further comprises:
determining a first perturbation range for a value of a first perturbation parameter; determining at least one first perturbation value for the first perturbation parameter based at least in part on the first perturbation range; and
generating the at least one perturbation of the target structure based on the at least one first perturbation value of the first perturbation parameter.
40. The method of clause 39, further comprising:
determining a second perturbation range for a value of a second perturbation parameter; and
determining at least one second perturbation value for the second perturbation parameter based at least in part on the second perturbation range;
wherein the at least one perturbation of the target structure is generated based on the at least one first perturbation value of the first perturbation parameter and the at least one second perturbation value of the second perturbation parameter.
41. The method of clause 36, wherein obtaining the measure of asymmetry corresponding to the at least one perturbation of the target structure comprises:
generating a simulation of an electromagnetic measurement of the at least one perturbation of the target structure; and
determining the measure of asymmetry based at least in part on the simulation.
42. The method of clause 36, wherein obtaining the measure of overlay corresponding to the at least one perturbation of the target structure comprises:
generating a model of the at least one perturbation of the target structure; and
determining the measure of overlay based at least in part on the model.
43. One or more non-transitory, machine-readable medium having instructions thereon, the instructions when executed by a processor being configured to perform the method of any of clauses 1 to 42.
44. A metrology system comprising:
a processor; and
one or more non-transitory, machine-readable medium as described in any of clause 1 to 42.

While the concepts disclosed herein may be used for manufacturing with a substrate such as a silicon wafer, it shall be understood that the disclosed concepts may be used with any type of manufacturing system (e.g., those used for manufacturing on substrates other than silicon wafers).

In addition, the combination and sub-combinations of disclosed elements may comprise separate embodiments. For example, one or more of the operations described above may be included in separate embodiments, or they may be included together in the same embodiment.

The descriptions above are intended to be illustrative, not limiting. Thus, it will be apparent to one skilled in the art that modifications may be made as described without departing from the scope of the claims set out below.

The descriptions above are intended to be illustrative, not limiting. Thus, it will be apparent to one skilled in the art that modifications may be made as described without departing from the scope of the claims set out below.

1.-16. (canceled)

17. Non-transitory, machine-readable media having instructions therein, the instructions, when executed by one or more processors, configured to cause the one or more processors to at least:
obtain a measure of asymmetry, wherein the measure of asymmetry is based, at least in part, on an electromagnetic measurement of a target structure; and
determine, by a hardware computer and based at least in part on a trained machine learning model, a measure of overlay for the target structure based on the measure of asymmetry.

18. The medium of claim 17, wherein the measure of overlay is an overlay error value or an overlay value.

19. The medium of claim 17, wherein the electromagnetic measurement comprises a first electromagnetic measurement at a first wavelength and a second electromagnetic measurement at a second wavelength and wherein the measure of asymmetry is determined based on a relationship between the first electromagnetic measurement and the second electromagnetic measurement.

20. The medium of claim 17, wherein the measure of asymmetry is a distance-to-origin, and wherein the distance-to-origin corresponds to a distance between a line, wherein the line is through a point corresponding to the first wavelength and a point corresponding to the second wavelength, and an origin point for a plot of asymmetric amplitude.

21. The medium of claim 20, wherein the measure of asymmetry is one or more selected from: an asymmetric intensity ratio, an asymmetric intensity difference, a set of offset angle values, and/or an offset angle difference value.

22. The medium of claim 17, wherein the instructions configured to cause the one or more processors to determine the measure of overlay for the target structure are further configured to cause the one or more processors to:
obtain a measure of symmetric overlay for the target structure based, at least in part, on the electromagnetic measurement of the target structure;
determine, based at least in part on the trained machine learning model, a measure of asymmetry-adjusted overlay based on the measure of asymmetry; and
determine the measure of overlay for the target structure based at least in part on the measure of symmetric overlay and the measure of asymmetry-adjusted overlay.

23. The medium of claim 17, wherein the instructions are further configured to cause the one or more processors to generate training data, wherein the trained machine learning model is trained based at least in part on the training data and wherein the training data comprises a measure of asymmetry associated with a measure of overlay for a set of perturbations of the target structure.

24. The medium of claim 23, wherein the instructions are further configured to cause the one or more processors to:
determine a set of perturbation parameters based at least in part on a stack structure, wherein the stack structure comprises the target structure and the set of perturbation parameters comprises overlay and/or critical distance; and
generate the set of perturbations of the target structure based, at least in part, on the set of perturbation parameters.

25. The medium of claim 23, wherein the measure of asymmetry is determined based on a simulation of the electromagnetic measurement of the set of perturbations of the target structure.

26. The medium of claim 23, wherein the measure of overlay is determined based on a model of a perturbation of the target structure, and wherein the set of perturbation parameters comprises critical distance and/or overlay.

27. The medium of claim 17, wherein the trained machine learning model is configured to output the measure of overlay based on an input, the input based at least in part on the electromagnetic measurement of the target structure.

28. The medium of claim 17, wherein the instructions are further configured to cause the one or more processors to identify, based at least in part on the trained machine learning model, a conformation of the target structure based on the measure of asymmetry.

29. The medium of claim 17, wherein the instructions are further configured to cause the one or more processors to:
obtain a measure of asymmetry corresponding to at least one perturbation of a target structure;
determine a feature vector as training data based, at least in part, on the measure of asymmetry corresponding to the at least one perturbation of the target structure.

30. The medium of claim 29, wherein the instructions are further configured to cause the one or more processors to:
obtain a measure of overlay corresponding to the at least one perturbation of the target structure
determine a supervisory signal based, at least in part, on the measure of overlay corresponding to the at least one perturbation of the target structure; and
label the feature vector for the at least one perturbation of the target structure with the supervisory signal.

31. The medium of claim 17, wherein the electromagnetic measurement is performed by an optical metrology apparatus and the target comprises one or more layers of diffraction gratings.

32. A method comprising:
obtaining a measure of asymmetry, wherein the measure of asymmetry is based, at least in part, on an electromagnetic measurement of a target structure; and
determine, by a hardware computer system and based at least in part on a trained machine learning model, a measure of overlay for the target structure based on the measure of asymmetry.

33. The method of claim 32, wherein the electromagnetic measurement comprises a first electromagnetic measurement at a first wavelength and a second electromagnetic measurement at a second wavelength and wherein the measure of asymmetry is determined based on a relationship between the first electromagnetic measurement and the second electromagnetic measurement.

34. The method of claim 32, wherein the measure of asymmetry is a distance-to-origin, and wherein the distance-to-origin corresponds to a distance between a line, wherein the line is through a point corresponding to the first wavelength and a point corresponding to the second wavelength, and an origin point for a plot of asymmetric amplitude.

35. The method of claim 32, wherein determining the measure of overlay for the target structure comprises:
obtaining a measure of symmetric overlay for the target structure based, at least in part, on the electromagnetic measurement of the target structure;
determining, based at least in part on the trained machine learning model, a measure of asymmetry-adjusted overlay based on the measure of asymmetry; and
determining the measure of overlay for the target structure based at least in part on the measure of symmetric overlay and the measure of asymmetry-adjusted overlay.

36. The method of claim 32, further comprising generating training data and training the machine learning model based at least in part on the training data, wherein the training data comprises a measure of asymmetry associated with a measure of overlay for a set of perturbations of the target structure.
